(19) United States
(12) Patent Application Publication
(10) Pub. No.: US 2002/0155700 A1
(43) Pub. Date: Oct. 24, 2002

(54) Method of forming a damascene structure

(76) Inventors: Tai-Ju Chen, Tainan (TW); Chien-Hsing Lin, Taichung (TW)

Correspondence Address: J C Patents Inc, 4 Venture, Suite 250, Irvine, CA, 92618, US

(21) Appl. No.: 09/871,400

(22) Filed: May 31, 2001

(30) Foreign Application Priority Data
Apr. 24, 2001 (TW) 90109737

(51) Int. Cl. H01L 21/4763; H01L 21/44

(52) U.S. Cl. 438/639; 438/638; 438/643; 438/653

(57) ABSTRACT

A method of forming a damascene structure. A porous dielectric layer is formed over a substrate. The porous dielectric layer is patterned to form an opening that exposes a portion of the substrate. A conformal low dielectric constant layer is formed over the substrate and the exposed surface of the opening. A portion of the low dielectric constant material is removed to form spacers on the sidewalls of the porous dielectric layer. A conformal barrier layer and a conductive layer are sequentially formed over the opening. Excess conductive material and barrier material outside the opening above the dielectric layer are removed to form a damascene structure.

### CROSS-REFERENCE TO RELATED APPLICATION

This application claims the priority benefit of Taiwan application serial no. 90109737, filed Apr. 24, 2001.

### BACKGROUND OF THE INVENTION

1. Field of Invention

The present invention relates to a method of forming multi-level interconnects for linking semiconductor devices. More particularly, the present invention relates to a method of forming a damascene structure.

1. Description of Related Art

As the semiconductor industry starts to fabricate deep sub-micron devices, copper often replaces aluminum as the material for forming interconnects. This is because copper has an anti-electromigration capacity 30 to 100 times that of aluminum and a copper via has a resistance only one-tenth to one-twentieth that of aluminum. In general, electrical resistance of copper is 30% lower than aluminum. Hence, copper lines together with a low dielectric constant (low K) inter-metal dielectric can lower resistor-capacitor (RC) delay and reduce electromigration. However, copper is difficult to etch, and hence the conventional method of fabricating copper lines is gradually being replaced by a damascene process.

In addition, the dielectric constant of a dielectric material can be reduced by reducing the degree of polarization and increasing the porosity of the material. Increasing the porosity of the dielectric material creates a porous structure. Because air has a dielectric constant of one, increasing density of pores inside a dielectric material lowers the dielectric constant considerably. Hence, in a damascene process, porous dielectric material is often used to form the inter-metal dielectric layer.

FIG. 1 is a schematic cross-section of a conventional dual damascene structure. As shown in FIG. 1, a porous dielectric layer 102 and an etching stop layer 104 are formed over a substrate 100. Another porous dielectric layer 106 and another etching stop layer 108 are formed over the etching stop layer 104. A dual damascene opening 110 is formed in the inter-metal dielectric layer 102 and the inter-metal dielectric layer 106. Thereafter, a conformal barrier layer 112 is formed over the exposed surface of the dual damascene opening 110. A copper layer 114 is formed over the etching stop layer 108 and fills the dual damascene opening 110. Finally, excess copper material in the copper layer 114 is removed to form a dual damascene structure.

The dual damascene structure is formed using porous inter-metal dielectric material. Since the dielectric material contains large number of pores, barrier layer material and copper may diffuse into these pores when the barrier material and the copper material is deposited. Ultimately, current may leak from the dielectric layer leading to a degradation of the device properties.

### SUMMARY OF THE INVENTION

Accordingly, one object of the present invention is to provide a method of forming a damascene structure that can prevent the diffusing of barrier material and conductive material into the pores of a porous inter-metal dielectric layer.

A second object of the invention is to provide a method of forming a damascene structure that can prevent current leaks due to the diffusing of barrier material and conductive material into the pores of a porous inter-metal dielectric layer.

To achieve these and other advantages and in accordance with the purpose of the invention, as embodied and broadly described herein, the invention provides a method of forming a damascene structure. A porous dielectric layer is formed over a substrate. The porous dielectric layer is patterned to form an opening that exposes a portion of the substrate. A conformal low dielectric constant layer is formed over the substrate and the exposed surface of the opening. A portion of the low dielectric constant material is removed to form spacers on the sidewalls of the porous dielectric layer. Thereafter, a conformal barrier layer and a conductive layer are sequentially formed over the opening. Finally, excess portions of the conductive layer and barrier layer outside the opening above the dielectric layer are removed to form a damascene structure.

One major aspect of this invention is the formation of low dielectric constant spacers on the sidewalls of damascene opening before depositing barrier material, thereby filling some of the pores in the inter-metal dielectric layer. Hence, the barrier material and conductive material are prevented from diffusing into the inter-metal dielectric layer. Consequently, current leaks from the ultimately formed device are reduced and production yield of the device is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-section of a conventional dual damascene structure; and

FIGS. 2A through 2G are schematic cross-sectional views showing the progression of steps for forming a dual damascene structure according to one preferred embodiment of this invention.

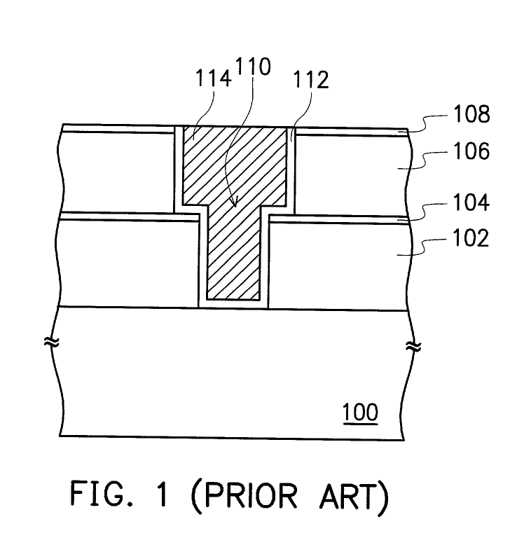

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

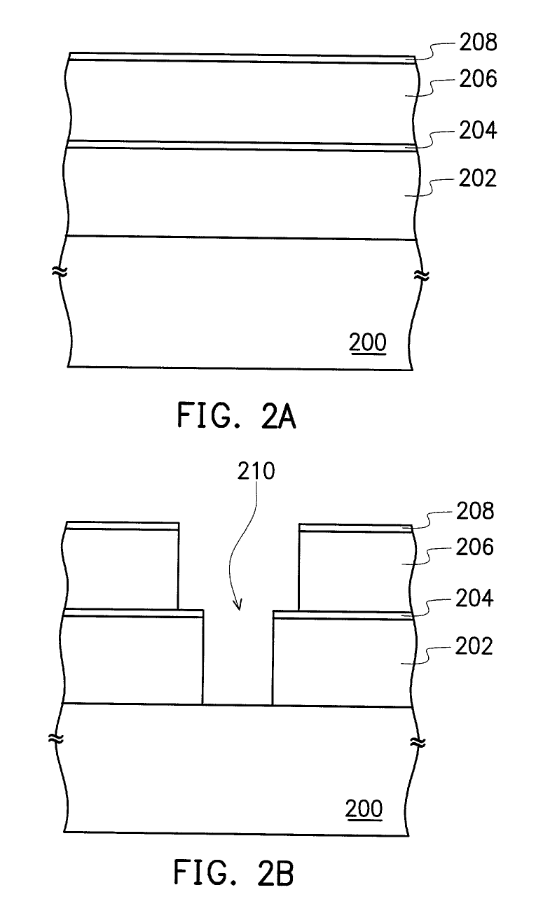

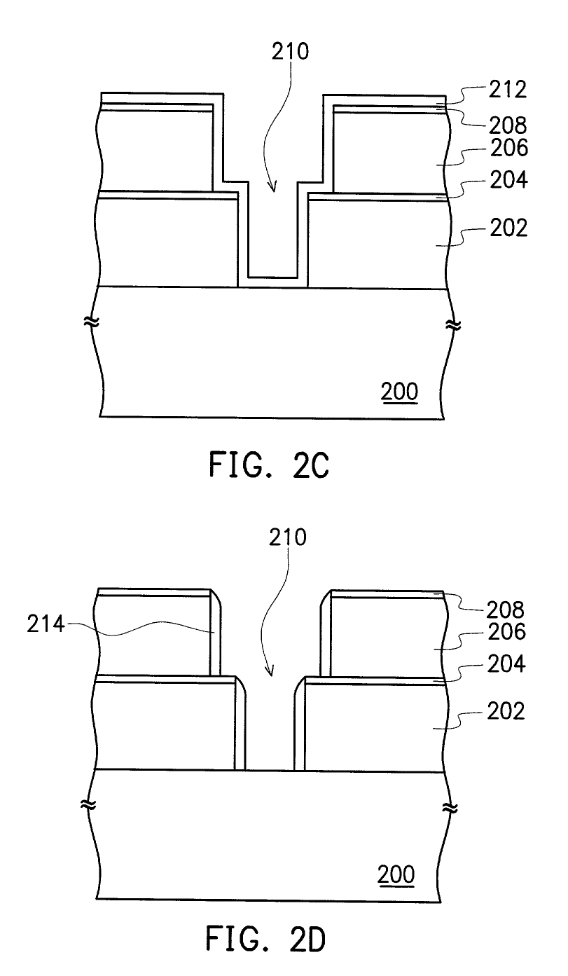

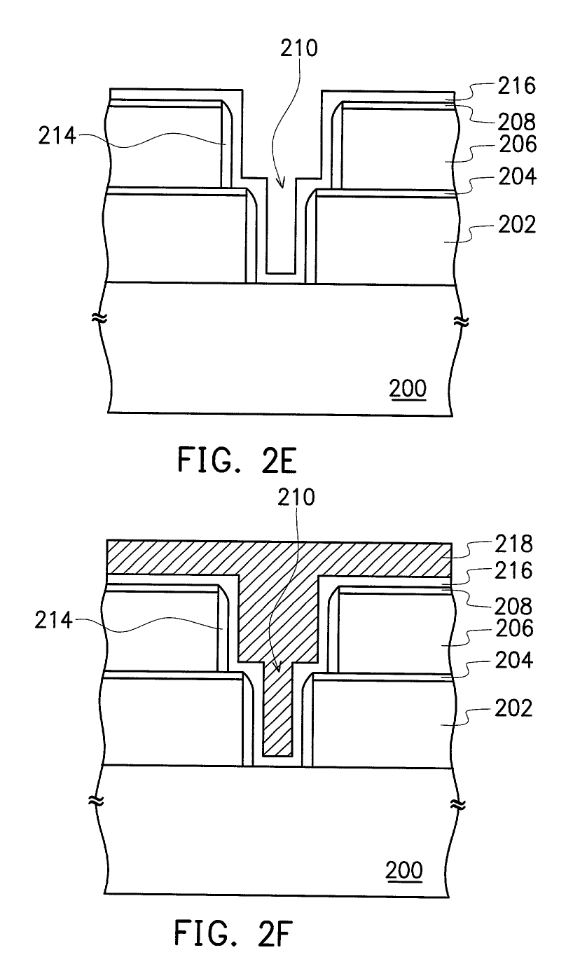

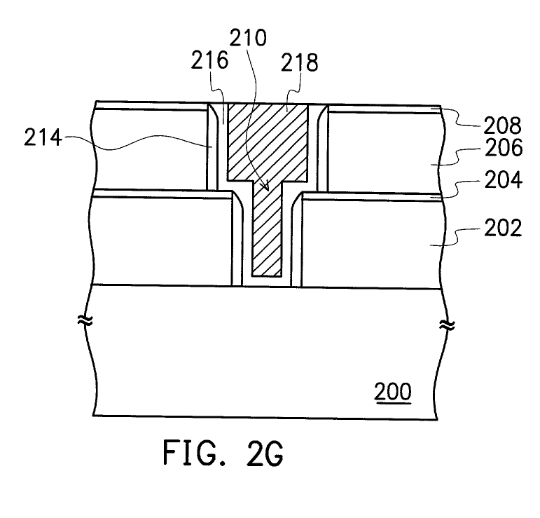

FIGS. 2A through 2G are schematic cross-sectional views showing the progression of steps for forming a dual damascene structure according to one preferred embodiment of this invention.

As shown in FIG. 2A, a substrate 200 (devices within the substrate 200 are not shown) is provided. A porous dielectric layer 202 is formed over the substrate 200. An etching stop layer 204 is formed over the porous dielectric layer 202. Thereafter, another porous dielectric layer 206 is formed over the etching stop layer 204. Finally, yet another etching stop layer 208 is formed over the porous dielectric layer 206. The porous dielectric layers 202 and 206 are low dielectric constant material layers such as a porous silica layer, a mesoporous silica layer, a porous silsesquioxane layer, a porous polyimide layer or a porous poly-(Arylene Ether) layer. Both porous dielectric layers 202 and 206 are formed, for example, by performing a spin-on-dielectric (SOD) operation. The etching stop layers 204 and 208 can be silicon nitride layers formed, for example, by chemical vapor deposition (CVD).

As shown in FIG. 2B, an opening 210 such as a dual damascene opening for forming a dual damascene structure, a trench for forming a conductive line, a via opening for forming a plug, a contact opening or any damascene opening for forming a damascene structure (a dual damascene opening is shown in the figure) is formed over the substrate 200. The method of forming the opening 210 includes a trench-first, a via-first and trench-via self-aligned process. Here, a via-first process is used as an illustration. To form the opening 210, a photoresist layer (not shown) is formed over the etching stop layer 208 and patterned. Using the photoresist layer as a mask, the porous dielectric layers 202 and 206 are etched to form a via opening until a portion of the substrate 200 is exposed. After removing the photoresist layer, another photoresist layer (not shown) is formed over the etching stop layer 208 and patterned. Using the patterned photoresist layer as a mask, the porous dielectric layer 206 is etched until the etching stop layer 204 is exposed, thereby forming a trench above a via opening.

As shown in FIG. 2C, a conformal low dielectric constant material layer 212 is formed over the etching stop layer 208 and the interior surfaces of the opening 210. The low dielectric constant material layer 212 can be, for example, a polyimide layer, a parylene layer, fluorinated polyimide layer. The low dielectric constant material layer 212 is formed by chemical vapor deposition (CVD), for example.

As shown in FIG. 2D, a portion of the low dielectric constant material layer 212 is removed to expose a portion of the etching stop layer 208, the etching stop layer 204 and the substrate 200 so that spacers 214 are formed on the sidewalls of the porous dielectric layers 202 and 206. The spacers 214 are formed, for example, by performing an anisotropic etching or a reactive ion etching.

As shown in FIG. 2E, a barrier layer 216 conformal to the interior surfaces of the opening 210 is formed over the etching stop layer 208. The barrier layer 216 can be a tantalum nitride (TaN) layer, a titanium nitride (TiN) layer or a titanium-silicon-nitride layer. To form the barrier layer 216, tantalum is first deposited over the silicon wafer by DC magnetron sputtering. The silicon wafer is transferred to a chamber containing gaseous nitrogen or ammonia. The silicon wafer is heated to a high temperature so that tantalum and nitrogen react in a nitridation reaction to form tantalum nitride. Alternatively, a reactive sputtering method may be used to form the tantalum nitride layer. First, a beam of ions is made to bombard against a tantalum target generating tantalum ions. The sputtered tantalum ions interact with dissociated nitrogen atoms in the plasma to form tantalum nitride and subsequently deposit on the silicon wafer. Due to the formation of spacers 214 on the sidewalls of the porous layers 202 and 206, barrier layer 216 material will not diffuse into the pores of the dielectric layers and lead to current leaks.

As shown in FIG. 2F, a conductive layer 218 is formed over the barrier layer 216 and fills the opening 210 completely. The conductive layer 218 is formed, for example, by physical vapor deposition (PVD), chemical vapor deposition (CVD) or sputtering. The conductive layer 218 may be made of material, such as copper, tungsten, aluminum or polysilicon. Since the sidewalls of the porous dielectric layers 202 and 206 are protected by spacers 214, conductive material cannot migrate into pores of the porous layers when the conductive layer 218 is deposited. Hence, leakage current from the device is greatly minimized.

As shown in FIG. 2G, chemical-mechanical polishing is carried out to remove excess portions of the conductive layer 218 outside the metal-filled opening 210 while using the barrier layer 216 as a polishing stop layer. So, the portions of the conductive layer 218 are removed by polishing until the barrier layer 216 is exposed. Finally, chemical-mechanical polishing capable of removing barrier and metal material is continued to remove the barrier layer 216 and expose the etching stop layer 208.

In this invention, low dielectric constant spacers 214 are formed on the sidewalls of the porous dielectric layers 202 and 206. Hence, the barrier material and conductive material are prevented from diffusing into the inter-metal dielectric layer. Consequently, current leaks from the subsequently formed device are reduced and production yield of the device is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a damascene structure, comprising:
providing a substrate having an opening therein and a porous dielectric layer thereon;
forming a low dielectric constant material layer over the substrate, wherein the low dielectric constant material layer is formed over the porous dielectric layer and conformal to an interior substrate surface of the opening;
removing a portion of the low dielectric constant material layer to form spacers on sidewalls of the porous dielectric layer; and
forming a conformal barrier layer over the interior surface of the opening; and
forming a conductive layer over the barrier layer for completely filling the opening.

2. The method of claim 1, wherein the low dielectric constant material layer comprises a material selected from a group consisting of polyimide, parylene and fluorinated polyimide.

3. The method of claim 1, wherein forming the spacers includes performing anisotropic etching.

4. The method of claim 3, wherein forming the spacers includes performing reactive ion etching.

5. The method of claim 1, wherein forming the low dielectric constant material layer includes chemical vapor deposition.

6. The method of claim 1, wherein the porous dielectric layer comprises a material selected from a group consisting of porous silica, mesoporous silica, porous silsesquioxane, porous polyimide and porous poly-(Arylene Ether).

7. The method of claim 1, wherein forming the porous dielectric layer includes spin-coating.

8. The method of claim 1, wherein the opening includes a dual damascene opening for forming a dual damascene structure, a trench for forming a conductive line, a via opening for forming a via plug, a contact opening and an opening for forming a damascene structure.

9. The method of claim 1, wherein the porous dielectric layer further contains an etching stop layer.

10. The method of claim 9, wherein the etching stop layer includes a silicon nitride layer.

11. The method of claim 1, wherein the conductive layer is selected from a group consisting of copper, tungsten, aluminum, and polysilicon.

12. A method of forming a damascene structure, comprising:
providing a substrate;
forming a first porous dielectric layer over the substrate;
forming a first etching stop layer over the first porous dielectric layer;
forming a second porous dielectric layer over the first etching stop layer;
forming a second etching stop layer over the second porous dielectric layer;
patterning the second etching stop layer, the second porous dielectric layer, the first etching stop layer and the first porous dielectric layer to form an opening that exposes a portion of the substrate;
forming spacers on sidewalls of the second porous dielectric layer and the first porous dielectric layer inside the opening;
forming a barrier layer over the substrate and conformal to interior surfaces of the opening;
forming a conductive layer over the barrier layer and completely filling the opening;
removing excess portions of the conductive layer outside the opening above the barrier layer; and
removing excess portions of the barrier layer outside the opening above the second etching stop layer.

13. The method of claim 12, wherein the spacers comprise a material selected from a group consisting of polyimide, parylene and fluorinated polyimide.

14. The method of claim 12, wherein the step of forming the spacers further includes:
forming a low dielectric constant material layer over the substrate, wherein the low dielectric constant material layer is conformal to a substrate surface and covers the second etching stop layer; and
performing an anisotropic etching to remove a portion of the dielectric constant material layer.

15. The method of claim 14, wherein the low dielectric constant material layer comprises a material selected from a group consisting of polyimide, parylene and fluorinated polyimide.

16. The method of claim 14, wherein the step of forming the low dielectric constant material layer includes chemical vapor deposition.

17. The method of claim 12, wherein the first and the second porous dielectric layer comprise a material selected from a group consisting of porous silica, mesoporous silica, porous silsesquioxane, porous polyimide and porous poly-(Arylene Ether).

18. The method of claim 12, wherein the step of forming the first and the second porous dielectric layer includes spin-coating.

19. The method of claim 12, wherein the opening includes a dual damascene opening for forming a dual damascene structure, a trench for forming a conductive line, a via opening for forming a via plug, a contact opening and an opening for forming a damascene structure.

20. The method of claim 12, wherein the first and the second etching stop layer includes a silicon nitride layer.

21. The method of claim 12, wherein the step of forming the first and the second etching stop layer includes performing a chemical vapor deposition.

22. The method of claim 12, wherein the conductive layer is selected from a group consisting of copper, tungsten, aluminum, and polysilicon.
